(19) United States
(12) Patent Application Publication
(10) Pub. No.: US 2026/0344234 A1
(43) Pub. Date: Oct. 29, 2026

(54) ORGANIC LIGHT EMITTING DISPLAY DEVICE

(71) Applicant: LG Display Co., Ltd., Seoul (KR)

(72) Inventors: Kwang-Jong KIM, Paju-si (KR); Su-Min GWON, Paju-si (KR)

(73) Assignee: LG Display Co., Ltd., Seoul (KR)

(21) Appl. No.: 19/655,255

(22) Filed: Apr. 22, 2026

(30) Foreign Application Priority Data
Apr. 29, 2025 (KR) 10-2025-0056553

(51) Int. Cl. H10K 59/35; H10K 50/115; H10K 59/38

(52) U.S. Cl. CPC H10K 59/35; H10K 50/115; H10K 59/38

(57) ABSTRACT

An organic light emitting display device includes a first electrode in each of blue and green pixel regions, a first HTL on the first electrode, first blue and green EMLs on the first HTL, a CGL on the first blue and green EMLs, a second HTL on the CGL, a first hole auxiliary layer on the second HTL, second blue and green EMLs on the first hole auxiliary layer, and a second electrode on the second blue and green EMLs. Each of the first and second blue EMLs includes first to third blue emitting layers, wherein a triplet energy of a material of the first hole auxiliary layer is greater than a triplet energy of a blue dopant, and a HOMO energy level thereof is lower than a HOMO energy level of a material of a second hole transporting layer.

### CROSS-REFERENCE TO RELATED APPLICATIONS

The present application claims the priority benefit of Korean Patent Application No. 10-2025-0056553 filed in the Republic of Korea on Apr. 29, 2025, which is hereby incorporated by reference in its entirety.

### BACKGROUND

### Technical Field

The present disclosure relates to a display device, and more specifically, to an organic light emitting display device providing an appropriate low-grayscale capacitance, high emitting efficiency and long lifespan and.

### Description of the Related Art

As the large-area display device is developed, the demand for the flat display device with small space occupancy is increasing. As one type of the flat display device, the technology of q liquid crystal (LC) display device, an organic light emitting display device and an inorganic light emitting display device is developing rapidly.

For example, the organic light emitting display device includes an organic light emitting diode (OLED). In the organic light emitting diode, holes from an anode and electrons from a cathode are combined to generate an exciton in an organic light emitting layer, and the exciton is transformed from an excited state to a ground state. As a result, the light is emitted from the OLED.

There is a limitation of an emitting efficiency and a lifespan in the OLED. Particularly, there is a big limitation of an emitting efficiency and a lifespan in the blue emission.

### BRIEF SUMMARY

The present disclosure is directed to an organic light emitting display device that substantially obviates one or more of the problems associated with the limitations and disadvantages of the related conventional art.

Various embodiments of the present disclosure provide an organic light emitting display device providing an appropriate low-grayscale capacitance, high emitting efficiency and long lifespan.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure is an organic light emitting display device comprising a substrate including a blue pixel region and a green pixel region; a first electrode disposed on the substrate and corresponding to each of the blue and green pixel regions; a first hole transporting layer disposed on the first electrode and corresponding to each of the blue and green pixel regions; a first blue emitting material layer disposed on the first hole transporting layer and corresponding to the blue pixel region; a first green emitting material layer disposed on the first hole transporting layer and corresponding to the green pixel region; a charge generation layer disposed on the first blue and green emitting material layers and corresponding to each of the blue and green pixel regions; a second hole transporting layer disposed on the charge generation layer and corresponding to each of the blue and green pixel regions; a first hole auxiliary layer on the second hole transporting layer and corresponding to each of the blue and green pixel regions; a second blue emitting material layer disposed on the first hole auxiliary layer and corresponding to the blue pixel region; a second green emitting material layer disposed on the first hole auxiliary layer and corresponding to the green pixel region; and a second electrode disposed on the second blue and green emitting material layers and corresponding to each of the blue and green pixel regions, wherein each of the first and second blue emitting material layers includes a first blue emitting layer, a second blue emitting layer on the first blue emitting layer and a third blue emitting layer on the second blue emitting layer, wherein the first blue emitting layer in the second blue emitting material layer includes a blue host and a blue dopant, wherein a triplet energy of a material of the first hole auxiliary layer is greater than a triplet energy of the blue dopant, and wherein a HOMO energy level of the material of the first hole auxiliary layer is lower than a HOMO energy level of a material of the second hole transporting layer.

It is to be understood that both the foregoing general description and the following detailed description are exemplary and explanatory and are intended to further explain the present disclosure as claimed.

### BRIEF DESCRIPTION OF THE SEVERAL VIEWS OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a schematic view illustrating an organic light emitting display device of the present disclosure.

FIG. 2 is a schematic circuit diagram of an organic light emitting display device of the present disclosure.

FIG. 3 is a schematic cross-sectional view of one pixel region of an organic light emitting display device according to a first embodiment of the present disclosure.

FIG. 4 is a schematic cross-sectional view of an organic light emitting display device according to the first embodiment of the present disclosure.

FIG. 5 is a schematic cross-sectional view of an OLED for an organic light emitting display device according to the first embodiment of the present disclosure.

FIG. 6 is a schematic cross-sectional view of an organic light emitting display device according to a second embodiment of the present disclosure.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts may be added unless ‘only’ is used. When a component is expressed in the singular, cases including the plural are included unless specific statement is described.

The expression “at least one of a, b, and c” described throughout the specification can encompass ‘a alone’, ‘b alone’, ‘c alone’, ‘a and b’, ‘a and c’, ‘band c’, or ‘all of a, b, and c’. The advantages and features of the present disclosure, and the methods for achieving them, will become apparent by referring to the embodiments described in detail below together with the accompanying drawings.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct (ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

The area, length, or thickness of each component described in the specification is illustrated for convenience of explanation, and the present disclosure is not necessarily limited to the area and thickness of the illustrated component.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Without specific description, a transistor constituting the pixel circuit of the present disclosure may include at least one of an oxide thin film transistor (Oxide TFT), an amorphous silicon TFT (a-Si TFT), and a low temperature poly silicon (LTPS) TFT.

The present disclosure relates to a tandem OLED device architecture in which each pixel includes first and second emitting stacks separated by a charge generation layer, combined with a multi layered blue emission structure. Each blue emitting material layer is divided into three sub layers with controlled host and dopant compositions, enabling positioning of the exciton recombination zone within a desired region. This arrangement addresses limitations associated with blue emission by improving emission efficiency and operational lifetime.

The structure further includes a hole auxiliary layer disposed between the second hole transport layer and the second emitting stack, with defined material properties. The hole auxiliary layer has a triplet energy greater than that of the blue dopant, a HOMO energy level lower than that of the adjacent hole transport layer, and a hole mobility lower than that of the hole transport layer. These relationships regulate charge transport and exciton confinement, thereby improving recombination characteristics while also adjusting electrical properties such as threshold voltage and low grayscale capacitance.

These structural and material relationships provide a device configuration that improves efficiency, lifetime, and low grayscale response characteristics. Additional configurations, such as extending the hole auxiliary layer across multiple pixel regions, support manufacturability while maintaining the described performance characteristics.

Reference will now be made in detail to some of the examples and preferred embodiments, which are illustrated in the accompanying drawings.

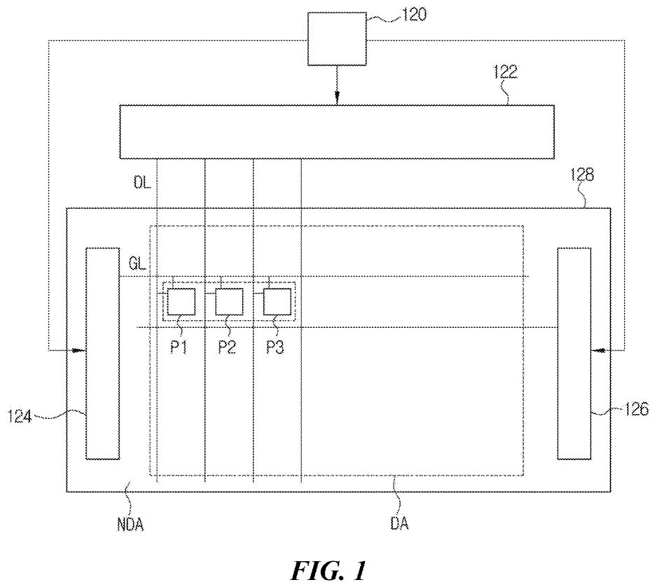

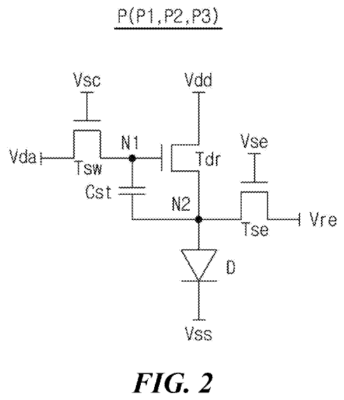

FIG. 1 is a schematic view illustrating an organic light emitting display device of the present disclosure, and FIG. 2 is a schematic circuit diagram of an organic light emitting display device of the present disclosure.

As shown in FIGS. 1 and 2, an organic light emitting display device according to an embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal and a gate control signal using an image signal and a plurality of timing signals including a data enable signal, a horizontal synchronization signal, a vertical synchronization signal and a clock signal transmitted from an external system. The timing controlling unit 120 transmits the image data and the data control signal to the data driving unit 122, and transmits the gate control signal to the first and second gate driving units 124 and 126.

The data driving unit 122 generates a data signal (a data voltage) Vda using the image data and the data control signal transmitted from the timing controlling unit 120 and transmits the data signal Vda to a data line DL of the display panel 128.

The first and second gate driving units 124 and 126 generate a gate signal (a gate voltage) Vsc and Vse using the gate control signal transmitted from the timing controlling unit 120 and applies the gate signal Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel region P.

Although the first and second gate driving units 124 and 126 are disposed in both side portions of the display panel 128 in the embodiment of FIG. 1, one gate driving unit may be disposed in one side portion of the display panel 128 in another embodiment.

The display panel 128 includes a display area DA at a central portion thereof and a non-display area NDA surrounding the display area DA. The display panel 128 displays an image using the gate signal Vsc and Vse and the data signal Vda. In the display panel 128, a plurality of gate lines GL and a plurality of data lines DL cross each other to define a pixel region P including first, second and third pixel regions P1, P2 and P3. For example, the first to third pixel regions P1, P2 and P3 may correspond to blue, green and red colors, respectively.

Each of the first to third pixel regions P1, P2 and P3 may include a plurality of transistors such as a switching transistor Tsw, a driving transistor Tdr and a sensing transistor Tse, a storage capacitor Cst and an organic light emitting diode D.

Although the switching transistor Tsw, the driving transistor Tdr and the sensing transistor Tse may have a negative type in the embodiment of FIG. 2, at least one of the switching transistor Tsw, the driving transistor Tdr and the sensing transistor Tse may have a positive type in another embodiment.

The switching transistor Tsw is switched according to a scan signal Vsc through the gate line GL to transmit a data signal Vda to a first node N1.

The driving transistor Tdr is switched according to a voltage of the first node N1 to transmit a high level signal (high level voltage) Vdd to a second node N2.

The sensing transistor Tse is switched according to a sensing signal (sensing voltage) Vse to transmit a reference signal (reference voltage) Vre to the second node N2 or transmit a voltage of the second node N2 to a reference line.

The storage capacitor Cst keeps the data signal Vda supplied to the first node N1 for one frame and stores a threshold voltage (Vth) of the driving transistor Tdr.

A first capacitor electrode of the storage capacitor Cst is connected to the first node N1, and a second capacitor electrode of the storage capacitor Cst is connected to the second node N2.

The organic light emitting diode D emits a light of a luminance proportional to a current of the driving transistor Tdr.

An anode of the organic light emitting diode D is connected to the second node N2, and a cathode of the organic light emitting diode D is connected to a low level power line to receive a low level signal (low level voltage) Vss.

The organic light emitting diode D may display an image having a luminance corresponding to the image data according to a driving of pixel circuits of the first to third pixel regions P1, P2 and P3.

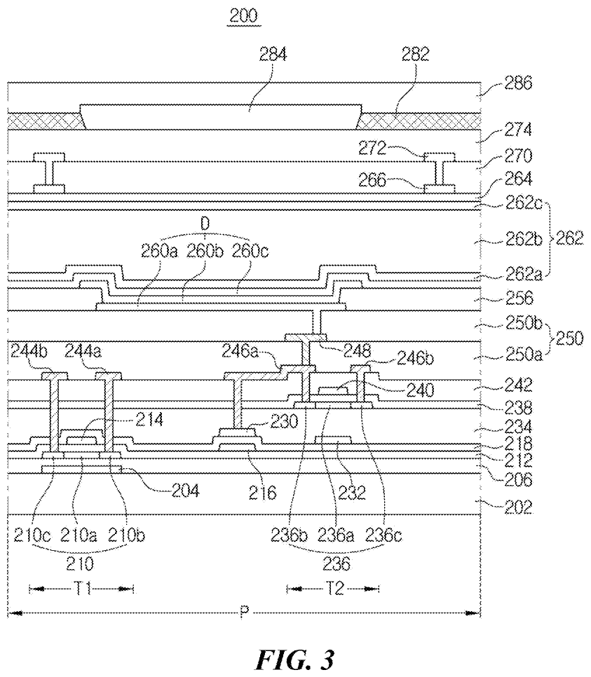

FIG. 3 is a schematic cross-sectional view of one pixel region of an organic light emitting display device according to a first embodiment of the present disclosure.

As shown in FIG. 3, an organic light emitting display device 200 includes a substrate 202 including a pixel region P and an OLED D over the substrate 202.

The substrate 202 may be a glass substrate or a plastic substrate. For example, the substrate 202 may be one of polyimide (PI) substrate, polyethersulfone (PES) substrate, polyethylenenaphthalate (PEN) substrate, polyethylene terephthalate (PET) substrate and polycarbonate (PC) substrate.

In an aspect of the present disclosure, the substrate 202 may have a triple-layered structure including a first polyimide layer, a second polyimide layer and an interlayer inorganic layer between the first and second polyimide layers. The interlayer inorganic layer may be formed of an inorganic insulating material, e.g., silicon oxide or silicon nitride.

A first light-shielding pattern 204 is disposed on the substrate 202. The light through the substrate 202 can be blocked by the first light-shielding pattern 204. For example, the first light-shielding pattern 204 may be formed of a metallic material, e.g., molybdenum (Mo), aluminum (Al), chromium (Cr), gold (Au), titanium (Ti), nickel (Ni), neodymium (Nd), copper (Cu) or their alloys, and may have a single-layered structure or a multi-layered structure.

A first buffer layer 206 covering the first light-shielding pattern 204 is disposed on the substrate 202. The first buffer layer 206 may serve to block external moisture and/or oxygen. For example, the first buffer layer 206 may be formed of an inorganic insulating material, e.g., silicon oxide or silicon nitride, and may have a single-layered structure or a multi-layered structure.

A first semiconductor layer 210 corresponding to the first light shielding pattern 204 is disposed on the first buffer layer 206. The first semiconductor layer 210 may include one of a poly-semiconductor material, an amorphous semiconductor material and an oxide semiconductor material. When the first light shielding pattern 204 and the first buffer layer 206 are omitted, the first semiconductor layer 210 may be directly disposed on the substrate 202.

In an aspect of the present disclosure, the first semiconductor layer 210 may be formed of a poly-semiconductor material, e.g., polycrystalline silicon. The first semiconductor layer 210 may include a first channel region 210a, a first source region 210b at one side of the first channel region 210a and a first drain region 210c at the other side of the first channel region 210a. Impurities may be dopped into the first source and drain regions 210b and 210c.

A first gate insulating layer 212 covering the first semiconductor layer 210 is disposed over the first buffer layer 206. For example, the first gate insulating layer 212 may be formed of an inorganic insulating material, e.g., silicon oxide or silicon nitride, and may have a single-layered structure or a multi-layered structure.

A first gate electrode 214 corresponding to the first channel region 210a of the first semiconductor layer 210 is disposed on the first gate insulating layer 212. In addition, a first capacitor electrode 216, which is spaced apart from the first gate electrode 214, is disposed on the first gate insulating layer 212.

The first gate electrode 214 and the first capacitor electrode 216 may be disposed at the same layer and formed of the same material. For example, each of the first gate electrode 214 and the first capacitor electrode 216 may be formed of a metallic material, e.g., Mo, Al, Cr, Au, Ti, Ni, Nd, Cu or their alloys, and may have a single-layered structure or a multi-layered structure.

A first interlayer insulating layer 218 covering the first gate electrode 214 and the first capacitor electrode 216 is disposed on the first gate insulating layer 212. For example, the first interlayer insulating layer 218 may be formed of an inorganic insulating material, e.g., silicon oxide or silicon nitride, and may have a single-layered structure or a multi-layered structure.

A second capacitor electrode 230 corresponding to the first capacitor electrode 216 and a second light shielding pattern 232 spaced apart from the second capacitor electrode 230 are disposed on the first interlayer insulating layer 218.

The second capacitor electrode 230 and the second light shielding pattern 232 may be disposed at the same layer and formed of the same material. For example, each of the second capacitor electrode 230 and the second light shielding pattern 232 may be formed of a metallic material, e.g., Mo, Al, Cr, Au, Ti, Ni, Nd, Cu or their alloys, and may have a single-layered structure or a multi-layered structure.

A second interlayer insulating layer 234 covering the second capacitor electrode 230 and the second light shielding pattern 232 is disposed on the first interlayer insulating layer 218. The second interlayer insulating layer 234 may serve to block external moisture and/or oxygen. For example, the second interlayer insulating layer 234 may be formed of an inorganic insulating material, e.g., silicon oxide or silicon nitride, or an organic insulating material, e.g., photo-acryl or benzocyclobutene (BCB), and may have a single-layered structure or a multi-layered structure.

A second semiconductor layer 236 corresponding to the second light shielding pattern 232 is disposed on the second interlayer insulating layer 234. The second semiconductor layer 236 may include one of a poly-semiconductor material, an amorphous semiconductor material and an oxide semiconductor material.

In an aspect of the present disclosure, the second semiconductor layer 236 may be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO). The second semiconductor layer 236 may include a second channel region 236a, a second source region 236b at one side of the second channel region 236a and a second drain region 236c at the other side of the second channel region 236a. Impurities may be dopped into the second source and drain regions 236b and 236c.

A second gate insulating layer 238 covering the second semiconductor layer 236 is disposed over the second interlayer insulating layer 234. For example, the second gate insulating layer 238 may be formed of an inorganic insulating material, e.g., silicon oxide or silicon nitride, and may have a single-layered structure or a multi-layered structure.

A second gate electrode 240 corresponding to the second channel region 236a of the second semiconductor layer 236 is disposed on the second gate insulating layer 238. For example, the second gate electrode 240 may be formed of a metallic material, e.g., Mo, Al, Cr, Au, Ti, Ni, Nd, Cu or their alloys, and may have a single-layered structure or a multi-layered structure.

A third interlayer insulating layer 242 covering the second gate electrode 240 is disposed on the second gate insulating layer 238. For example, the third interlayer insulating layer 242 may be formed of an inorganic insulating material, e.g., silicon oxide or silicon nitride, and may have a single-layered structure or a multi-layered structure.

A first source electrode 244a, a first drain electrode 244b, a second source electrode 246a and a second drain electrode 246b are disposed on the third interlayer insulating layer 242.

The first source electrode 244a and the first drain electrode 244b are respectively connected to the first source region 210b and the first drain region 210c via contact holes through the third interlayer insulating layer 242, the second gate insulating layer 238, the second interlayer insulating layer 234, the first interlayer insulating layer 218 and the first gate insulating layer 212. The first source electrode 244a is connected to the first capacitor electrode 216 via a contact hole through the third interlayer insulating layer 242, the second gate insulating layer 238, the second interlayer insulating layer 234 and the first interlayer insulating layer 218.

The second source electrode 246a and the second drain electrode 246b are respectively connected to the second source region 236b and the second drain region 236c via contact holes through the third interlayer insulating layer 242 and the second gate insulating layer 238. The second source electrode 246a is connected to the second capacitor electrode 230 via a contact hole through the third interlayer insulating layer 242, the second gate insulating layer 238 and the second interlayer insulating layer 234.

The first source electrode 244a, and the first drain electrode 244b, second source electrode 246a and the second drain electrode 246b may be disposed at the same layer and formed of the same material. For example, each of the first source electrode 244a, and the first drain electrode 244b, second source electrode 246a and the second drain electrode 246b may be formed of a metallic material, e.g., Mo, Al, Cr, Au, Ti, Ni, Nd, Cu or their alloys, and may have a single-layered structure or a multi-layered structure.

The first semiconductor layer 210, the first gate electrode 214, the first source electrode 244a and the first drain electrode 244b constitute a first TFT T1, and the second semiconductor layer 236, the second gate electrode 240, the second source electrode 246a and the second drain electrode 246b constitute a second TFT T2. For example, the first TFT T1 may be a switching TFT, and the second TFT T2 may be a driving TFT. The first and second capacitor electrodes 216 and 230 constitute a storage capacitor.

The organic light emitting display device 200 of the present disclosure includes the first and second TFTs T1 and T2. Each of the first semiconductor layer 210 of the first TFT T1 and the second semiconductor layer 236 of the second TFT T2 may include one of a poly-semiconductor material, an amorphous semiconductor material and an oxide semiconductor material, and at least one of the first semiconductor layer 210 of the first TFT T1 and the second semiconductor layer 236 of the second TFT T2 may include the oxide semiconductor material.

In an aspect of the present disclosure, the first semiconductor layer 210 of the first TFT T1 may be formed of the poly-semiconductor material, e.g., polycrystalline silicon, and the second semiconductor layer 236 of the second TFT T2 may be formed of the oxide semiconductor material.

In FIG. 3, the first gate electrode 214, the first source electrode 244a and the first drain electrode 244b are disposed over the first semiconductor layer 210, and the second gate electrode 240, the second source electrode 246a and the second drain electrode 246b are disposed over the second semiconductor layer 236. Namely, each of the first and second TFTs T1 and T2 have a coplanar structure. Alternatively, in each of the first and second TFTs T1 and T2, a gate electrode may be disposed under the semiconductor layer, and the source and drain electrode may be disposed on or over the semiconductor layer. Namely, each of the first and second TFTs T1 and T2 may have an inverted-staggered structure.

A planarization layer 250 covering the first source and drain electrodes 244a and 244b and the second source and drain electrodes 246a and 246b is disposed on the third interlayer insulating layer 242. The planarization layer 250 may be formed of an organic insulating material, e.g., photo-acryl or BCB.

The planarization layer 250 may include a lower planarization layer (e.g., a first planarization layer) 250a on the first source and drain electrodes 244a and 244b and the second source and drain electrodes 246a and 246b and an upper planarization layer (e.g., a second planarization layer) 250b on the lower planarization layer 250a.

A connection electrode 248 corresponding to the second source electrode 246a is disposed on the lower planarization layer 250a. The connection electrode 248 may connected to the second source electrode 246a through a contact hole in the lower planarization layer 250a. For example, the connection electrode 248 may be formed of a metallic material, e.g., Mo, Al, Cr, Au, Ti, Ni, Nd, Cu or their alloys, and may have a single-layered structure or a multi-layered structure.

The upper planarization layer 250b is disposed on the lower planarization layer 250a to cover the connection electrode 248, and a first electrode 260a is disposed on the upper planarization layer 250b. The first electrode 260a corresponds to the connection electrode 248 and is connected to the connection electrode 248 through a contact hole in the upper planarization layer 250b. Alternatively, the connection electrode 248 may be omitted, and the first electrode 260a may be directly connected to the second source electrode 246a.

For example, the first electrode 260a is separately formed in each pixel region P. The first electrode 260a may be an anode and may include a transparent conductive oxide (TCO) layer, which is formed of a conductive material, e.g., a transparent conductive oxide material, having a relatively high work function, and a reflective layer.

For example, the transparent conductive oxide material may include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al: ZnO, AZO), and the reflective layer may include at least one of silver (Ag), an alloy of Ag and one of palladium (Pd), Cu, In and Nd and aluminum-palladium-copper alloy (APC). For example, the first electrode 260a may have a double-layered structure of Ag/ITO or APC/ITO or a triple-layered structure of ITO/Ag/ITO or ITO/APC/ITO.

The bank 256 is formed on the upper planarization layer 250b at a boundary of the pixel region. The bank 256 covers an edge of the first electrode 260a and has a first opening to expose a center of the first electrode 260a. The bank 256 may include a light-absorbing particle, e.g., a black particle, to have a light-absorbing property.

An organic light emitting layer 260b covering the first electrode 260a and the bank 256 is disposed. The organic light emitting layer 260b contacts the first electrode 260a in the first opening of the bank 256.

A second electrode 260c is formed over the substrate 202 where the organic emitting layer 260b is formed. The second electrode 260c covers an entire surface of the display area. The second electrode 260c may be formed of at least one of ITO, IZO, Al, Ag, Cu, Pb, magnesium (Mg), Mo, Ti and their alloy and have a single-layered structure or a multi-layered structure. The second electrode 260c may have a thin profile (small thickness) to provide a light transmittance property (or a semi-transmittance property).

The first electrode 260a, the organic light emitting layer 260b and the second electrode 260c constitute an OLED D. The OLED D may emit the red, green and blue light in the red, green and blue pixel region, respectively.

In the organic light emitting display device 200, the light from the organic light emitting layer 260b passes through the second electrode 260c to display an image. Namely, the organic light emitting display device 200 of the present disclosure is a top-emission type display device.

An encapsulation layer (or encapsulation film) 262 is formed on the second electrode 260c to prevent penetration of moisture into the OLED D. The encapsulation layer 262 may cover an entire substrate 202. The encapsulation layer 262 includes a first inorganic insulating layer 262a, an organic insulating layer 262b and a second inorganic insulating layer 262c sequentially stacked, but it is not limited thereto.

For example, each of the first and second inorganic insulating layer 262a and 262c may be formed of an inorganic insulating material, e.g., silicon oxide or silicon nitride, and the organic insulating layer 262b may be formed of an organic insulating material, e.g., an acryl resin, an epoxy resin, a phenol resin, a polyamide resin or a PI resin.

A second buffer layer 264 is disposed on the encapsulating layer 262. The second buffer layer 264 may serve to block external moisture and/or oxygen. For example, the second buffer layer 264 may be formed of an inorganic insulating material, e.g., silicon oxide or silicon nitride, and may have a single-layered structure or a multi-layered structure.

A bridge pattern 266 is disposed on the second buffer layer 264. The bridge pattern 266 may correspond to a boundary of the pixel region P. For example, the bridge pattern 266 may be formed of one of ITO, IZO, Al, Ag, Cu, Pb, Mg, Mo, Ti and their alloy and have a single-layered structure or a multi-layered structure.

A touch interlayer insulating layer (e.g., an organic interlayer insulating layer) 270 is disposed on the bridge pattern 266 and over an entire substrate 202. For example, the touch interlayer insulating layer 270 may be formed of an organic insulating material, e.g., photo-acryl or BCB, and may have a single-layered structure or a multi-layered structure.

A touch electrode 272 is disposed on the touch interlayer insulating layer 270. The touch electrode 272 may correspond to a boundary of the pixel region P. The touch electrode 272 are connected to the bridge pattern 266 through a contact hole formed in the touch interlayer insulating layer 270.

For example, the touch electrode 272 may be formed of one of ITO, IZO, Al, Ag, Cu, Pb, Mg, Mo, Ti and their alloy and have a single-layered structure or a multi-layered structure.

A third buffer layer 274 is disposed on the touch electrode 272. For example, the third buffer layer 274 may be formed of an inorganic insulating material, e.g., silicon oxide or silicon nitride, and may have a single-layered structure or a multi-layered structure.

A black matrix 282 is disposed on the third buffer layer 274. The black matrix 282 is positioned at a boundary of the pixel region P and has a second opening in correspondence to the OLED D. Namely, the second opening of the black matrix 282 corresponds to the first opening of the light-shielding bank 256.

A color filter layer 284 corresponding to the OLED D is disposed on the third buffer layer 274. Namely, the color filter layer 284 may correspond to the second opening of the black matrix 282. The color filter layer 284 may include a red color filter corresponding to the red pixel region, a green color filter corresponding to the green pixel region and a blue color filter corresponding to the blue pixel region.

A color conversion layer may be disposed between the OLED D and the color filter layer 284. The color conversion layer may include a red color conversion layer corresponding to the red pixel region, a green color conversion layer corresponding to the green pixel region and a blue color conversion layer corresponding to the blue pixel region. For example, the color conversion layer may include a quantum dot.

In FIG. 3, the bridge pattern 266, the touch electrode 272, the black matrix 282 and the color filter layer 284 are disposed over the OLED D. Alternatively, at least one of the bridge pattern 266, the touch electrode 272, the black matrix 282 and the color filter layer 284 may be omitted. For example, the color filter layer 284 may be disposed on the encapsulation layer 262, and the color conversion layer may be disposed between the encapsulation layer 262 and the color filter layer 284.

A protection layer 286 is disposed on the black matrix 282 and the color filter layer 284 and over an entire substrate 202. For example, the protection layer 286 may be formed of an organic insulating material, e.g., photo-acryl or BCB, and may have a single-layered structure or a multi-layered structure.

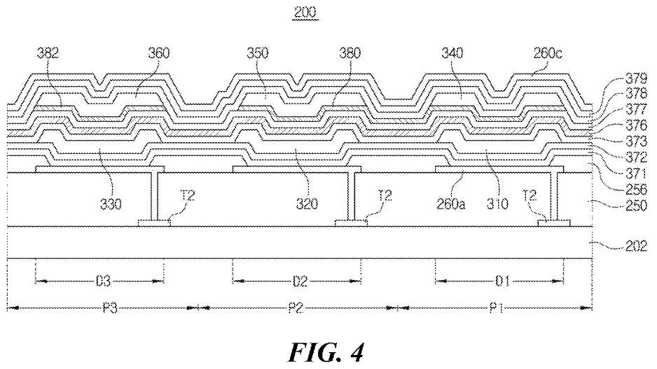

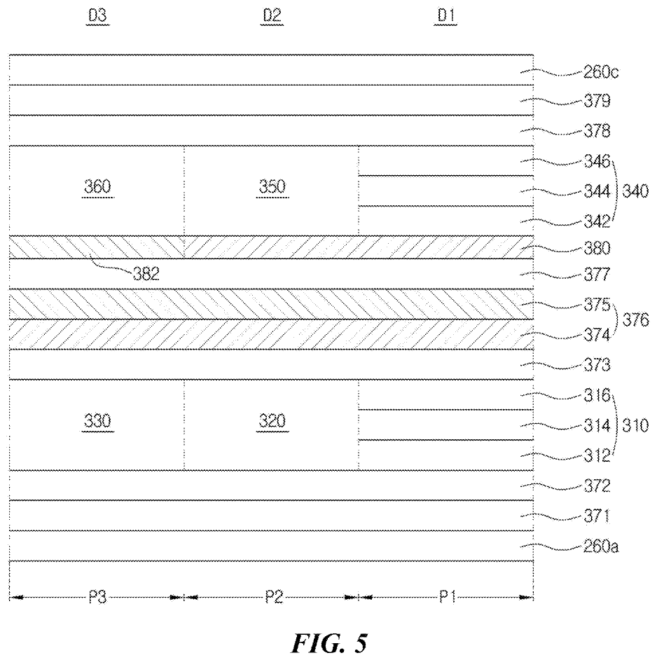

FIG. 4 is a schematic cross-sectional view of an organic light emitting display device according to the first embodiment of the present disclosure, and FIG. 5 is a schematic cross-sectional view of an OLED for an organic light emitting display device according to the first embodiment of the present disclosure.

Referring to FIGS. 4 and 5, first, second and third OLEDs D1, D2 and D3 are disposed over the substrate 202.

A first pixel region P1 as a blue pixel region, a second pixel region P2 as a green pixel region and a third pixel region P3 as a red pixel region are defined on the substrate 202, and the first to third OLEDs D1, D2 and D3 are disposed in the first to third pixel regions P1, P2 and P3, respectively. The first OLED D1 is a blue OLED emitting blue light, the second OLED D2 is a green OLED emitting green light, and the third OLED D3 is a red OLED emitting red light.

The second TFT T2 as a driving TFT is disposed on the substrate 202 and in each of the first to third pixel regions P1, P2 and P3, and each of the first to third OLEDs D1, D2 and D3 is connected to the second TFT T2 through a contact hole in the planarization layer 250.

Each of the first to third OLEDs D1, D2 and D3 has a double-stack structure. Namely, the first OLED D1 includes the first electrode 260a, a first emitting stack, which includes a first blue emitting material layer (EML) 310 and a first hole transporting layer (HTL) 371, a second emitting stack, which includes a second blue EML 340 and a second HTL 377, and the second electrode 260c. The second OLED D2 includes the first electrode 260a, a first emitting stack, which includes a first green EML 320 and the first HTL 371, a second emitting stack, which includes a second green EML 350 and a second HTL 377, and the second electrode 260c. The third OLED D3 includes the first electrode 260a, a first emitting stack, which includes a first red EML 330 and the first HTL 371, a second emitting stack, which includes a second red EML 360 and a second HTL 377, and the second electrode 260c. In each of the first to third OLEDs D1, D2 and D3, a charge generation layer (CGL) 376 is disposed between the first and second emitting stacks.

In addition, in each of the first and second OLEDs D1 and D2, a first hole auxiliary layer 380 may be disposed between the second blue EML 340 and the second HTL 377 and between the second green EML 350 and the second HTL 377. The first hole auxiliary layer 380 in the first OLED D1 and the first hole auxiliary layer 380 in the second OLED D2 may be connected to each other. Namely, the first hole auxiliary layer 380 in the second OLED D2 may extend from the first hole auxiliary layer 380 in the first OLED D1.

Moreover, in the third OLED D3, a second hole auxiliary layer 382 may be disposed between the second red EML 360 and the second HTL 377. The second hole auxiliary layer 382 in the third pixel region P3 is separated from the first hole auxiliary layer 380 in the first and second pixel regions P1 and P2.

Each of the first and second blue EMLs 310 and 340 has a triple-layered structure. Namely, the first blue EML 310 includes a first blue emitting layer 312 on the first HTL 371, a second blue emitting layer 314 on the first blue emitting layer 312 and a third blue emitting layer 316 on the second blue emitting layer 314, and the second blue EML 340 includes a first blue emitting layer 342 on the first hole auxiliary layer 380, a second blue emitting layer 344 on the first blue emitting layer 342 and a third blue emitting layer 346 on the second blue emitting layer 344.

Each of the first blue emitting layer 312 in the first blue EML 310 and the first blue EML 342 in the second blue EML 340 includes a first blue host and a first blue dopant. Each of the second blue emitting layer 314 in the first blue EML 310 and the second blue emitting layer 344 in the second blue EML 340 includes a second blue host and a second blue dopant. Each of the third blue emitting layer 316 in the first blue EML 310 and the third blue emitting layer 346 in the second blue EML 340 includes a third blue host and a third blue dopant.

In each of the first blue emitting layer 312 in the first blue EML 310 and the first blue EML 342 in the second blue EML 340, a weight % of the first blue host is greater than that of the first blue dopant. In each of the second blue emitting layer 314 in the first blue EML 310 and the second blue emitting layer 344 in the second blue EML 340, a weight % of the second blue host is greater than that of the second blue dopant. In each of the third blue emitting layer 316 in the first blue EML 310 and the third blue emitting layer 346 in the second blue EML 340, a weight % of the third blue host is greater than that of the third blue dopant.

The first and third blue hosts may be same material, and the second blue host may be different from the first and third blue hosts. The first to third dopants may be same material.

Each of the first and second green EMLs 320 and 350 and the first and second red EMLs 330 and 360 may have a single-layered structure. Each of the first and second green EMLs 320 and 350 may include a green host and a green dopant, and each of the first and second red EMLs 330 and 360 may include a red host and a red dopant.

The first HTL 371 may include a first hole transporting material, and the second HTL 377 may include a second hole transporting material. The first and second hole transporting materials may be same or different. The first hole auxiliary layer 380 may include a first hole auxiliary material, and the second hole auxiliary layer 382 may include a second hole auxiliary material. The first and second hole auxiliary materials may be same or different.

A material of the first hole auxiliary layer 380 has a triplet energy being greater than the first blue dopant. For example, a difference between a triplet energy of the material of the first hole auxiliary layer 380 and a triplet energy of the first blue dopant may be 0.2 eV or more, preferably in a range of 0.2 to 0.3 eV. In addition, the first blue host has a triplet energy being smaller than the first blue dopant and being greater than the second blue host. Moreover, the material of the first hole auxiliary layer 380 has a highest occupied molecular orbital (HOMO) energy level being lower than a material of the second HTL 377.

Various methods of determining the HOMO energy level are known to the skilled person. For example, the HOMO energy level can be determined using a conventional surface analyzer such as an AC3 surface analyzer made by RKI instruments. The surface analyzer may be used to interrogate a single film (neat film) of a compound with a thickness of 50 nm. The LUMO energy level can be calculated as follows:

LUMO=HOMO-bandgap.

The bandgap may be calculated using any conventional method known to the skilled person, such as from a UV-vis measurement of a single film with a thickness of 50 nm. For example, this can be done using a SCINCO S-3100 spectrophotometer. The HOMO and LUMO values of the compounds of the examples and embodiments disclosed herein may be determined in this way. Namely, the HOMO and LUMO values may be experimentally or empirically determined values of thin films, such as 50 nm films.

As a result, an exciton is confined in the second blue host having a relatively low triplet energy, and a recombination zone is presented in the second blue emitting layer 314 at a center of the first blue EML 310 and the second blue emitting layer 344 at a center of the second blue EML 340. Accordingly, the emitting efficiency and the lifespan of the first OLED D1 are improved.

A material of the first hole auxiliary layer 380 has a hole mobility being smaller than a material of the second HTL 377. The hole mobility of the material of the second HTL 377 may be 10 times or more than that of the material of the first hole auxiliary layer 380. For example, the hole mobility of the material of the first hole auxiliary layer 380 may be in a range 1*10-8 cm²/Vs to 1*10-5 cm²/Vs, and the hole mobility of the material of the second HTL 377 may be in a range 1*10-5 cm²/Vs to 1*10-3 cm²/Vs. However, it is not limited thereto. Namely, in the organic light emitting display device 200 of the present disclosure, a relationship between small and large of the hole mobility of the material of the first hole auxiliary layer 380 and the hole mobility of the material of the second HTL 377 is one of important facts, while the hole mobility range of the material of the first hole auxiliary layer 380 and the material of the second HTL 377 may not be an important fact.

The hole mobility was measured using a hole-only device (HOD) and J-V fitting based on the space charge limited current (SCLC) relationship.

Each of the first and second OLEDs D1 and D2 have an appropriate (or a desired) low-grayscale capacitance so that a low-grayscale response time (e.g., response speed) of the organic light emitting display device 200 can be improved and/or a driving voltage of the organic light emitting display device 200 can be reduced. In other words, each of the first and second OLEDs D1 and D2 has an appropriate threshold voltage so that a low-grayscale response time of the organic light emitting display device 200 can be improved and/or a driving voltage of the organic light emitting display device 200 can be reduced.

When the first hole auxiliary layer 380, the second HTL 377, the first blue emitting layers 312 and 342 and the second blue emitting layers 314 and 344 do not satisfy the above conditions, the low-grayscale capacitance of the first and second OLEDs D1 and D2 is degraded so that the low-grayscale response time may be decreased and/or the driving voltage may be increased. However, in the organic light emitting display device 200 of the present disclosure, the first hole auxiliary layer 380, the second HTL 377, the first blue emitting layers 312 and 342 and the second blue emitting layers 314 and 344 satisfy the above conditions, the malfunction of the organic light emitting display device 200 can be prevented and/or the driving voltage of the organic light emitting display device 200 can be reduced along with improving emitting efficiency and lifespan.

The green dopant of the second green EML 350 may have a triplet energy being smaller than a material of the first hole auxiliary layer 380. For example, a difference between a triplet energy of the green dopant and a triplet energy of the material of the first hole auxiliary layer 380 may be 0.3 eV or more, preferably in a range of 0.3 to 0.4 eV. The triplet energy of the green dopant may be smaller than that of the first blue dopant. A difference between a triplet energy of the first blue dopant and a triplet energy of the green dopant may be smaller than a difference between a triplet energy of the material of the first hole auxiliary layer 380 and a triplet energy of the first blue dopant.

As a result, the emitting efficiency and the lifespan of the second OLED D2 is increased, and the first and second OLEDs D1 and D2 have further appropriate low-grayscale capacitance.

Since the first auxiliary layer 380 of the same material is disposed in each of the first and second pixel regions P1 and P2, an increase of a number of a fine metal mask can be prevented even though the organic light emitting display device 200 includes the second blue EML 340 having a triple-layered structure and the first hole auxiliary layer 380.

In each of the first to third OLEDs D1, D2 and D3, the first HTL 371 is disposed between the first electrode 260a as an anode and each of the first blue, green and red EMLs 310, 320 and 330. The first HTL 371 may be formed of the same material as the second HTL 377.

The first emitting stack of each of the first to third OLEDs D1, D2 and D3 may further include at least one of an electron blocking layer (EBL) 372 between the first HTL 371 and each of the first blue, green and red EMLs 310, 320 and 330 and a first hole blocking layer (HBL) 373 on each of the first blue, green and red EMLs 310, 320 and 330.

The second emitting stack of each of the first to third OLEDs D1, D2 and D3 may further include at least one of a second HBL 378 on each of the second blue, green and red EMLs 340, 350 and 360 and an electron transporting layer (ETL) 379 on the second HBL 378.

In addition, the first emitting stack of each of the first to third OLEDs D1, D2 and D3 may further include at least one of a hole injection layer (HIL) between the first HTL 371 and the first electrode 260a and an ETL between the first HBL 373 and the CGL 376.

In addition, the second emitting stack of each of the first to third OLEDs D1, D2 and D3 may further include an electron injection layer (EIL) between the ETL 379 and the second electrode 260c as a cathode.

The CGL 376 may include an n-type CGL 374 and a p-type CGL 375 on the n-type CGL 374. An electron is transferred and/or injected into the first emitting stack by the n-type CGL 374, and a hole is transferred and/or injected into the second emitting stack by the p-type CGL 375.

Each of the first HTL 371, the EBL 372, the first HBL 373, the CGL 376, the second HTL 377, the second HBL 378 and the ETL 379 in the first to third pixel regions P1, P2 and P3 is connected to each other to be continuous. On the other hand, each of the first and second blue EMLs 310 and 340 is formed to be an island shape in the first pixel region P1, each of the first and second green EMLs 320 and 350 is formed to be an island shape in the second pixel region P2, and each of the first and second red EMLs 330 and 360 and the second hole auxiliary layer 382 is formed to be an island shape in the third pixel region P3. In addition, the first hole auxiliary layer 380 is formed to be an island shape to correspond to the first and second pixel regions P1 and P2.

As mentioned above, in the organic light emitting display device 200 of the present disclosure, the OLED D has a double-stack structure, and each of the first and second blue EMLs 310 and 340 has a triple-layered structure. A material of the second HTL 377, a material of the first hole auxiliary layer 380, the first blue host and the first blue dopant of the first blue emitting layer 342 and the second blue host and the second blue dopant of the second blue emitting layer 344 satisfy the above conditions (or relations) so that the emitting efficiency and the lifespan of the first OLED D1 in the first pixel region P1 as a blue pixel region can be improved.

In addition, a material of the second HTL 377 and a material of the first hole auxiliary layer 380 satisfy the above conditions, each of the first and second OLEDs D1 and D2 has an appropriate low-grayscale capacitance. Accordingly, the low-grayscale response time of the organic light emitting display device 200 can be improved, and/or the driving voltage of the organic light emitting display device 200 can be reduced.

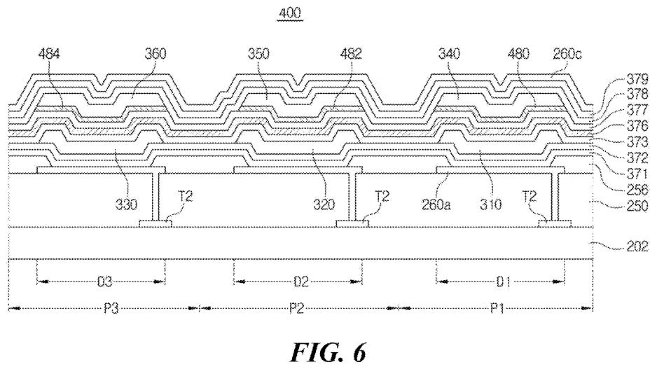

FIG. 6 is a schematic cross-sectional view of an organic light emitting display device according to a second embodiment of the present disclosure.

In comparison to the organic light emitting display device 200 according to the first embodiment of the present disclosure, the organic light emitting display device 400 according to the second embodiment of the present disclosure has a difference in a hole auxiliary layer. Accordingly, the explanation is focused on the hole auxiliary layer.

As shown in FIG. 6, the organic light emitting display device 400 includes a substrate 202 includes a first hole auxiliary layer 480 between the second HTL 377 and the second blue EML 340 in the first pixel region P1 as a blue pixel region, a second hole auxiliary layer 482 between the second HTL 377 and the second green EML 350 in the second pixel region P2 as a green pixel region and a third hole auxiliary layer 484 between the second HTL 377 and the second red EML 360 in the third pixel region P3 as a red pixel region.

The first to third hole auxiliary layers 480, 482 and 484 are spaced apart from each other. Namely, in the organic light emitting display device 200 according to the first embodiment of the present disclosure, the first hole auxiliary layer 380 is continuous in the first and second pixel regions P1 and P2, while in the organic light emitting display device 400 according to the second embodiment of the present disclosure, the first hole auxiliary layer 480 in the first pixel region P1 and the second hole auxiliary layer 482 in the second pixel region P2 are formed of the same material and spaced apart from each other.

### Evaluation of OLED's Properties

The threshold voltage (Vth) and the emitting efficiency of the OLED (Ex) in the organic light emitting display device according to the first embodiment of the present disclosure and the OLED (Ref) without a first hole auxiliary layer were measured and listed in Table 1. The properties of the OLED were measured by driving at 1 kHz and performing a voltage sweep using the Probe station B1500A equipment.

TABLE 1

| | |
|---|---|
| a blue pixel region | a green pixel region |

| | Vth | Efficiency | Vth | Efficiency |
|---|---|---|---|---|
| Ref | — | 100% | — | 100% |
| Ex | +0.1 V | 102% | +0.07 V | 102% |

As shown in Table 1, the OLED includes a hole auxiliary layer between the second HTL and each of the second blue EML and the second green EML so that the low-grayscale capacitance (threshold voltage) is increased and the emitting efficiency is improved. Accordingly, the emitting efficiency of the organic light emitting display device is improved and the low-grayscale response time is improved.

It will be apparent to those skilled in the art that various modifications and variations can be made in the embodiments of the present disclosure without departing from the technical idea or scope of the present disclosure. Thus, it is intended that the modifications and variations cover this disclosure provided they come within the scope of the appended claims and their equivalents.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An organic light emitting display device, comprising:
a substrate including a blue pixel region and a green pixel region;
a first electrode disposed on the substrate and corresponding to each of the blue and green pixel regions;
a first hole transporting layer disposed on the first electrode and corresponding to each of the blue and green pixel regions;
a first blue emitting material layer disposed on the first hole transporting layer and corresponding to the blue pixel region;
a first green emitting material layer disposed on the first hole transporting layer and corresponding to the green pixel region;
a charge generation layer disposed on the first blue and green emitting material layers and corresponding to each of the blue and green pixel regions;
a second hole transporting layer disposed on the charge generation layer and corresponding to each of the blue and green pixel regions;
a first hole auxiliary layer disposed on the second hole transporting layer and corresponding to each of the blue and green pixel regions;
a second blue emitting material layer disposed on the first hole auxiliary layer and corresponding to the blue pixel region;
a second green emitting material layer disposed on the first hole auxiliary layer and corresponding to the green pixel region; and
a second electrode disposed on the second blue and green emitting material layers and corresponding to each of the blue and green pixel regions,
wherein each of the first and second blue emitting material layers includes a first blue emitting layer, a second blue emitting layer on the first blue emitting layer and a third blue emitting layer on the second blue emitting layer,
wherein the first blue emitting layer in the second blue emitting material layer includes a blue host and a blue dopant,
wherein a triplet energy of a material of the first hole auxiliary layer is greater than a triplet energy of the blue dopant in the first blue emitting layer of the second blue emitting material layer, and
wherein a HOMO energy level of the material of the first hole auxiliary layer is lower than a HOMO energy level of a material of the second hole transporting layer.

2. The organic light emitting display device according to claim 1, wherein a difference between the triplet energy of the material of the first hole auxiliary layer and the triplet energy of the blue dopant in the first blue emitting layer of the second blue emitting material layer is 0.2 eV or more.

3. The organic light emitting display device according to claim 1, wherein each of the first and second green emitting material layers has a single-layered structure, and the second green emitting material layer includes a green host and a green dopant.

4. The organic light emitting display device according to claim 3, wherein the triplet energy of the material of the first hole auxiliary layer is greater than a triplet energy of the green dopant.

5. The organic light emitting display device according to claim 4, wherein the triplet energy of the blue dopant is greater than a triplet energy of the green dopant.

6. The organic light emitting display device according to claim 1, wherein a hole mobility of a material of the first hole auxiliary layer is smaller than a hole mobility of a material of the second hole transporting layer.

7. The organic light emitting display device according to claim 6, wherein the hole mobility of the first hole auxiliary layer is in a range 1*10⁻⁸ cm²/Vs to 1*10⁻⁵ cm²/Vs, and
wherein the hole mobility of the second hole transporting layer is in a range 1*10⁻⁵ cm²/Vs to 1*10⁻³ cm²/Vs.

8. The organic light emitting display device according to claim 1, wherein the substrate further includes a red pixel region, and
wherein in the red pixel region,
the first electrode is disposed on the substrate;
the first hole transporting layer is disposed on the first electrode;
a first red emitting material layer is disposed on the first hole transporting layer;
the charge generation layer is disposed on the first red emitting material layer;
the second hole transporting layer is disposed on the charge generation layer;
a second hole auxiliary layer is disposed on the second hole transporting layer;
a second red emitting material layer is disposed on the second hole auxiliary layer; and
the second electrode is disposed on the second red emitting material layer.

9. The organic light emitting display device according to claim 8, wherein each of the first and second red emitting material layers has a single-layered structure.

10. The organic light emitting display device according to claim 9, wherein the first and second hole auxiliary layers are formed of different materials.

11. The organic light emitting display device according to claim 9, wherein the first and second hole auxiliary layers are separated from each other.

12. The organic light emitting display device according to claim 1, wherein the first hole auxiliary layer in the blue pixel region is continuous from the first hole auxiliary layer in the green pixel region.

13. The organic light emitting display device according to claim 1, wherein the first hole auxiliary layer in the blue pixel region is separated from the first hole auxiliary layer in the green pixel region.

14. The organic light emitting display device according to claim 1, further comprising:
an encapsulation layer on the second electrode.

15. The organic light emitting display device according to claim 14, further comprising:
a color filter layer disposed on the encapsulation layer and including a blue color filter pattern in the blue pixel region and a green color filter pattern in the green pixel region.

16. The organic light emitting display device according to claim 15, wherein the substrate further includes a red pixel region, and
wherein the color filter layer further includes a red color filter pattern in the red pixel region.

17. The organic light emitting display device according to claim 15, further comprising:
a color conversion layer between the encapsulation layer and the color filter layer.

18. The organic light emitting display device according to claim 17, wherein the color conversion layer includes a quantum dot.
